(19) United States
(12) Patent Application Publication
(10) Pub. No.: US 2007/0037406 A1
(43) Pub. Date: Feb. 15, 2007

(54) METHODS OF FABRICATING A SEMICONDUCTOR DEVICE USING A PHOTOSENSITIVE POLYIMIDE LAYER AND SEMICONDUCTOR DEVICES FABRICATED THEREBY

(76) Inventors: Joo-Sung PARK, Gyeonggi-do (KR); Jun-Yong NOH, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/424,498

(22) Filed: Jun. 15, 2006

(30) Foreign Application Priority Data
Aug. 9, 2005 (KR) 10-2005-0072860

(51) Int. Cl. H01L 21/31; H01L 21/469

(52) U.S. Cl. 438/758

(57) ABSTRACT

A method of fabricating a semiconductor device includes forming a photo-sensitive polyimide layer on a semiconductor substrate, patterning the photo-sensitive polyimide layer using a mask having a layer for adjusting light transmittance, and forming an epoxy molding compound on the substrate having the photo-sensitive polyimide layer patterns.

### CROSS-REFERENCE TO RELATED APPLICATIONS

This application claims priority from Korean Patent Application No. 10-2005-0072860, which was filed on 9 Aug. 2005. Korean Patent Application No. 10-2005-0072860 is incorporated by reference in its entirety.

### BACKGROUND

1. Technical Field

This disclosure relates to methods of fabricating a semiconductor device and semiconductor devices fabricated thereby, and more particularly, to methods of fabricating a semiconductor device using a photo-sensitive polyimide layer and semiconductor devices fabricated thereby.

2. Description of the Related Art

Semiconductor devices formed on a semiconductor substrate, e.g. semiconductor chips, are encapsulated by an assembly process to exclude effects from the external environment. The assembly process includes forming an epoxy molding compound covering the semiconductor chips. In addition, surfaces of the semiconductor chips are covered with a passivation layer and a photo-sensitive polyimide layer by back-end processes prior to the assembly process. In this case, the photo-sensitive polyimide layer acts as a buffer layer which alleviates stresses applied to the semiconductor chips by the epoxy molding compound.

Further, the photo-sensitive polyimide layer prevents alpha particles from penetrating into the semiconductor chips. The alpha particles remove charges generated or induced within a depletion layer of the PN junction formed within the semiconductor chip. When the semiconductor chips are volatile memory devices having memory cells, each of the memory cells includes a data storage element connected to the PN junction. For example, when the memory cells are Dynamic Random Access Memory (DRAM) cells, the data storage element corresponds to a cell capacitor. In this case, data stored in the cell capacitor, e.g. charges, may be removed by the alpha particles. Consequently, the photo-sensitive polyimide layer is required to enhance the reliability of the semiconductor device.

In recent years, a photo-sensitive polyimide layer having the properties of a typical photoresist layer is widely used in fabricating the semiconductor device in order to simplify the back-end processes.

FIGS. 1A to 1D are views illustrating a method of fabricating a conventional semiconductor device using a photo-sensitive polyimide layer.

Referring to FIG. 1A, an inter-insulating layer 2 is formed on a semiconductor substrate 1. Pads 3 are formed on the inter-insulating layer 2. A passivation layer 4 is formed on the entire surface of the semiconductor substrate having the pads 3. The passivation layer 4 is a single layer of a silicon nitride material, or a combination layer of a silicon oxide material and a silicon nitride material. A photo-sensitive polyimide layer 5 is formed on the passivation layer 4.

Referring to FIGS. 1B and 1C, light is radiated on a typical photo mask 6 and light transmitted through the photo mask 6 is radiated on the semiconductor substrate having the photo-sensitive polyimide layer 5 to uncover the pads 3. The photo mask 6 has an opaque pattern 7 for selectively exposing the photo-sensitive polyimide layer 5 above the pads 3. Light transmitted through the photo mask 6 having the opaque pattern 7 selectively exposes the photo-sensitive polyimide layer 5 above the pads 3. As a result, an exposure region is formed above the pads 3. The exposure region is removed during a subsequent development step, so that the passivation layer 4 above the pads 3 is uncovered. The uncovered passivation layer 4 is etched using the developed photo-sensitive polyimide layer as an etch mask to form pad windows 11 over the pads 3.

In addition, the photo mask 6 has a number of slits 8 in regions other than the opaque pattern 7. Light transmitted through the photo mask 6 having the slits 8 exposes the photo-sensitive polyimide layer 5. As a result, concaves 9 are formed on a surface of the photo-sensitive polyimide layer 5 by the subsequent development process. For example, when each width of the slits is w, the concaves, each having a width of t, are formed on the surface of the photo-sensitive polyimide layer 5. Accordingly, the surface area of the photo-sensitive polyimide layer having the concaves is relatively increased compared to that of the photo-sensitive polyimide layer having a planar-type surface.

The opaque pattern 7 is formed of a chrome metal layer. In addition, the slits 8 are also formed of chrome metal layers. The photo mask 6 has chrome metal layer patterns formed on a quartz substrate 10. Slits are formed in the chrome metal layer on the quartz substrate 10 except in regions where the opaque pattern 7 is formed.

An epoxy molding compound (not shown) is formed on the photo-sensitive polyimide layer having the concaves 9 and the pad windows 11 to cover the photo-sensitive polyimide layer. Accordingly, the contact area between the epoxy molding compound and the photo-sensitive polyimide layer having the concaves 9 relatively increases, so that adhesion between the photo-sensitive polyimide layer and the epoxy molding compound is enhanced.

The above-described method of fabricating the conventional semiconductor device simultaneously performs an exposure process for forming the concaves 9 and an exposure process for forming the pad windows 11. That is, the intensity of light radiated on the photo mask 6 is uniform. Accordingly, the method of fabricating the conventional semiconductor device has a limit in process margin when increasing the width of the slits 8 to perform the exposure process.

Referring to FIG. 1D, when increasing the width w′ of slits 8′ formed on a photo mask 6′ to perform the exposure and development processes, openings 12 having an increased width t′ are formed in the photo-sensitive polyimide layer 5. The openings 12 uncover the passivation layer 4. Accordingly, when an epoxy molding compound provided by a subsequent assembly process covers the photo-sensitive polyimide layer having the openings 12, the epoxy molding compound is in direct contact with the passivation layer. That is, since the photo-sensitive polyimide layer is not present between the epoxy molding compound and the passivation layer, the above-described advantages of the photo-sensitive polyimide layer cannot be used. Accordingly, the method of fabricating the conventional semiconductor device has a limit in process margin.

A method of fabricating a semiconductor device using the photo-sensitive polyimide layer is disclosed in Japanese Laid-Open Patent Publication No. 2002-270735. According to the Japanese Laid-Open Patent Publication No. 2002-270735, a mask having a void pattern of 1 μm² finer than the resolution limit of the photo-sensitive polyimide layer is used to form a concave having a size of 1 μm² on a surface of the photo-sensitive polyimide layer. Accordingly, it is difficult to form a concave having a size of 1 μm² or more on the surface of the photo-sensitive polyimide layer using the mask having the void pattern. In addition, the mask has a void pattern finer than the resolution limit of the photo-sensitive polyimide layer, so that the concaves are not uniformly formed on the surface of the photo-sensitive polyimide layer.

In addition, according to the Japanese Laid-Open Patent Publication No. 2002-270735, a mask having a hole pattern with a size of 1 μm² or more is used to form a concave having a size of 1 μm² to 3 μm² on the surface of the photo-sensitive polyimide layer. In this case, when the photo-sensitive polyimide layer is exposed by the same light source to simultaneously form the concave and the hole on the pad, the concave may uncover the passivation layer. Accordingly, there is a limit in increasing the hole size of the hole pattern mask. Further, according to the Japanese Laid-Open Patent Publication No. 2002-270735, the flare (i.e. light leakage) at the time of exposure is used to form a concave having a size of 100 μm² to 500 μm² on the surface of the photo-sensitive polyimide layer. In this case, it is difficult to form the hole on the pad using the flare effect at the time of exposure, and it is not easy to adjust the amount of light leakage, i.e., the flare at the time of exposure, either.

### SUMMARY

A method of fabricating a semiconductor device includes forming a photo-sensitive polyimide layer on a semiconductor substrate, patterning the photo-sensitive polyimide layer using a mask having a layer for adjusting light transmittance, and forming an epoxy molding compound on the substrate having the photo-sensitive polyimide layer patterns.

### BRIEF DESCRIPTION OF THE DRAWINGS

The foregoing and other objects, features and advantages of the invention will be apparent from the more particular description of preferred embodiments of the invention, as illustrated in the accompanying drawings. The drawings are not necessarily to scale, emphasis instead being placed upon illustrating the principles of the invention.

FIGS. 1A to 1D are cross-sectional views illustrating a method of fabricating a conventional semiconductor device using a photo-sensitive polyimide layer.

FIGS. 2A to 2F are cross-sectional views illustrating a method of fabricating a semiconductor device in accordance with some embodiments of the invention.

FIGS. 3A to 3H are cross-sectional views illustrating a method of fabricating a semiconductor device in accordance with other embodiments of the invention.

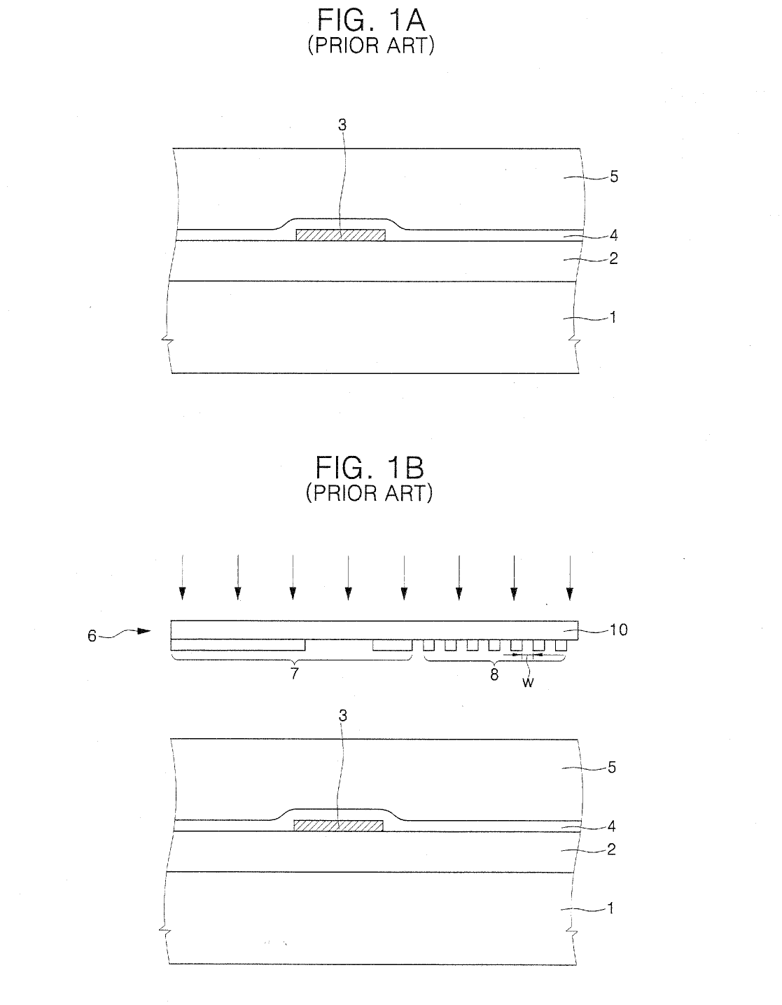

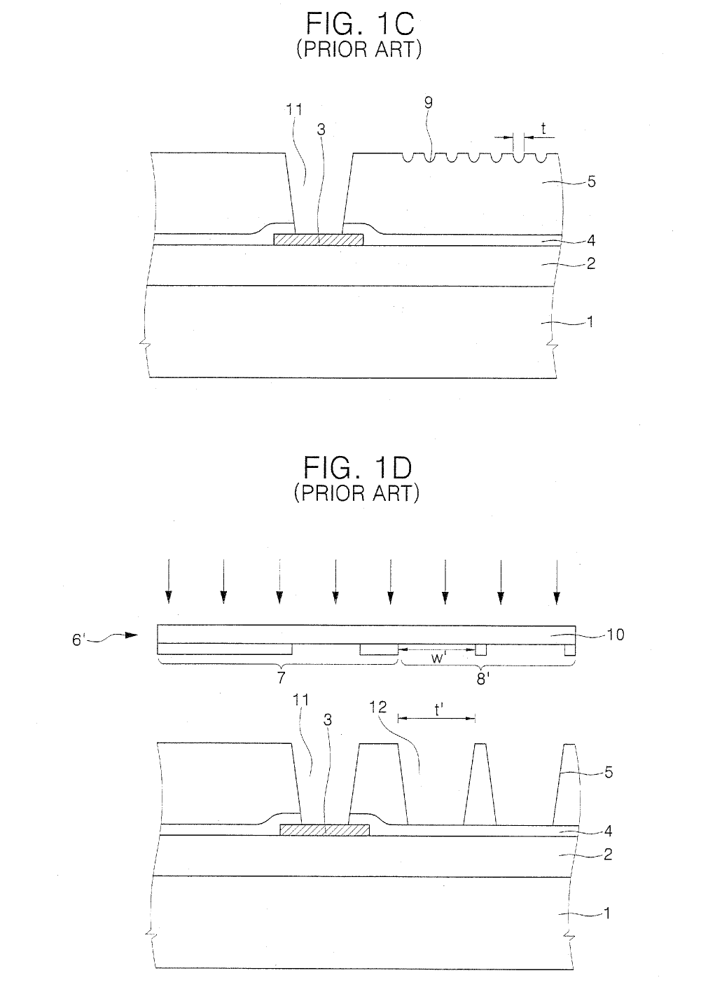

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. In the drawings, the thickness of layers and regions are exaggerated for clarity. In addition, when a layer is described to be formed on another layer or on a substrate, this means that the layer may be formed on the other layer or on the substrate, or a third layer may be interposed between the layer and the other layer or the substrate. Like numbers refer to like elements throughout the specification.

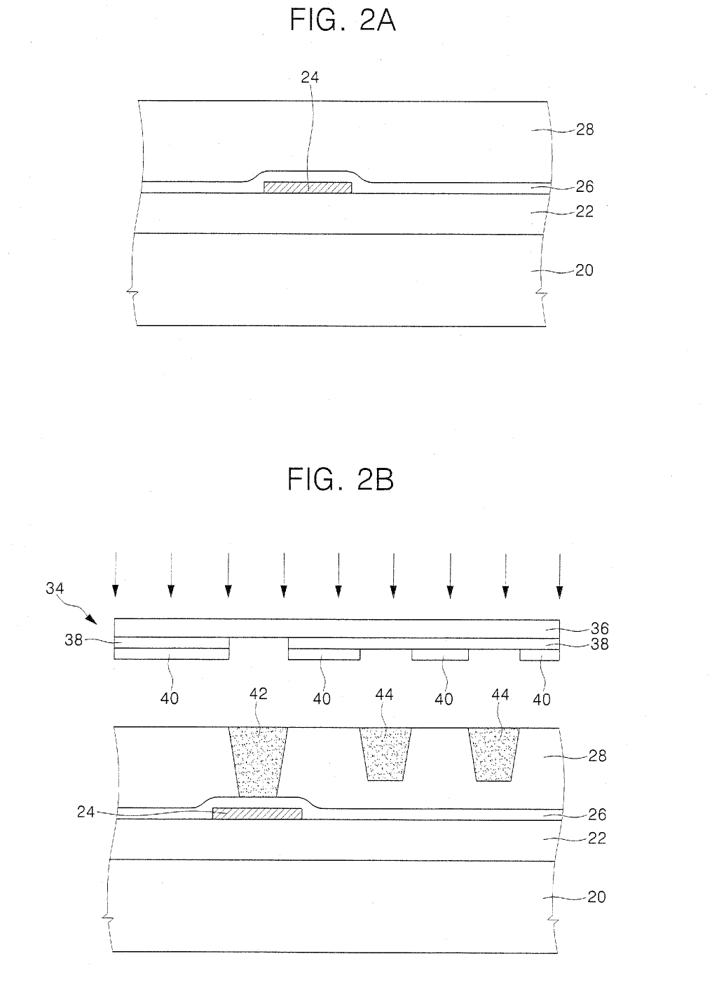

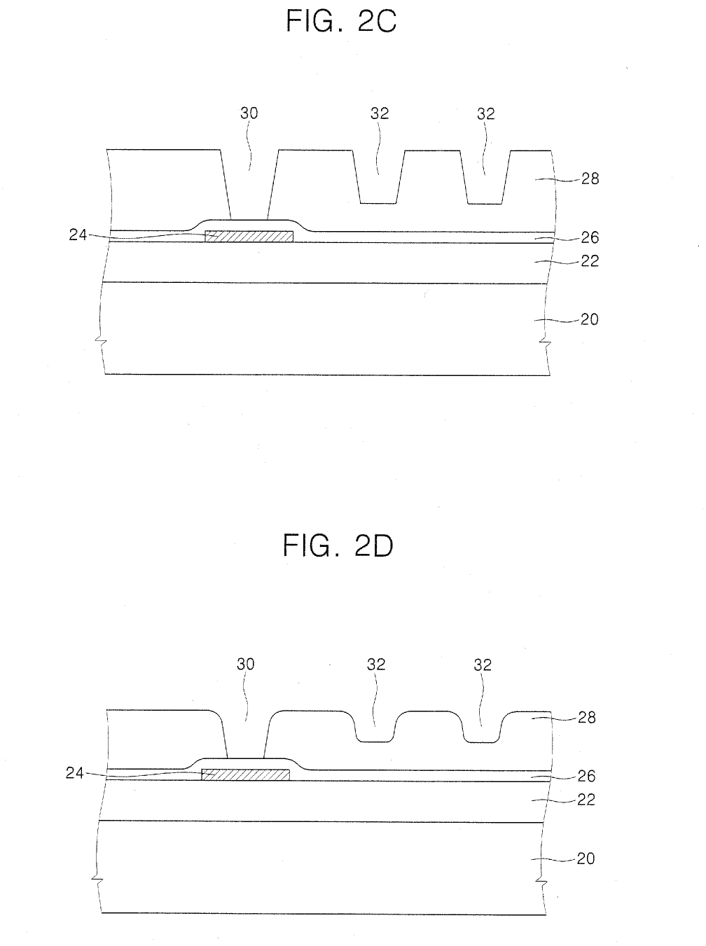

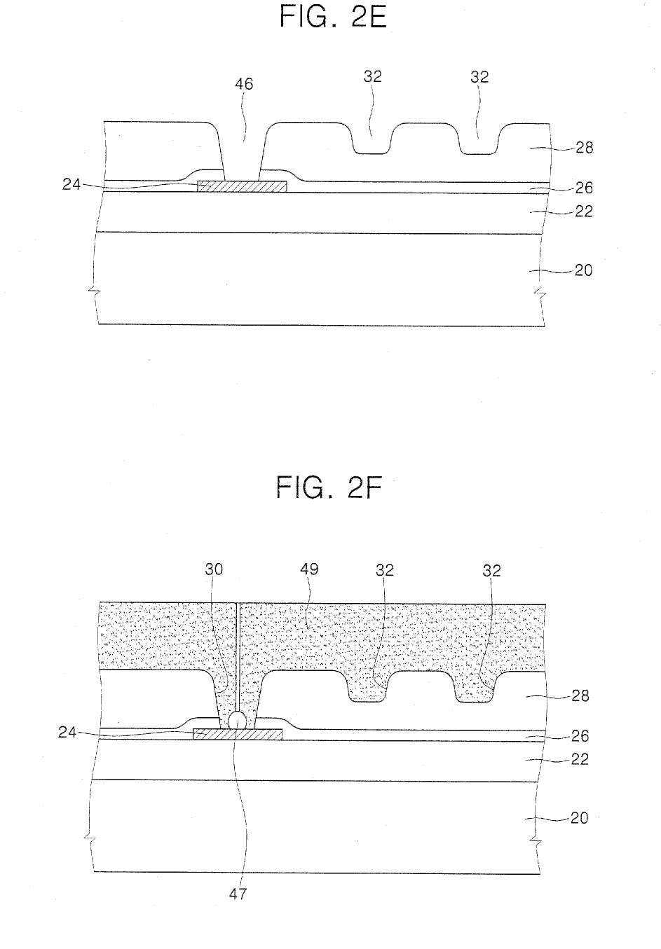

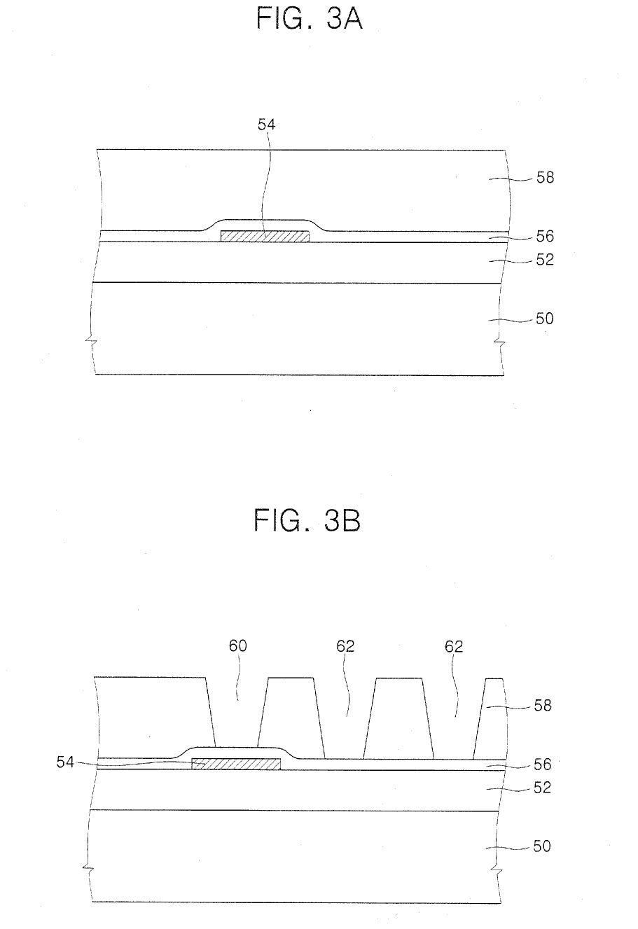

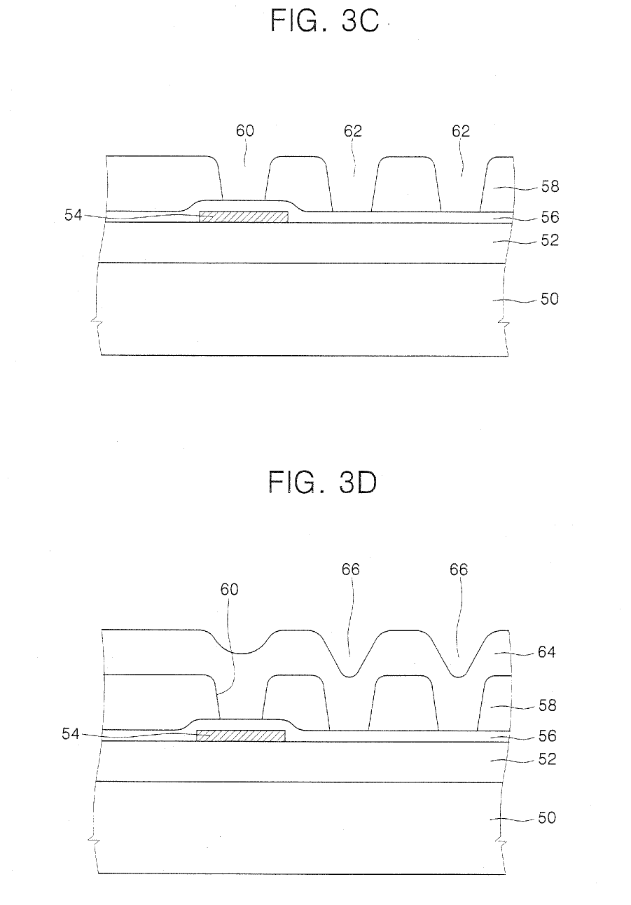

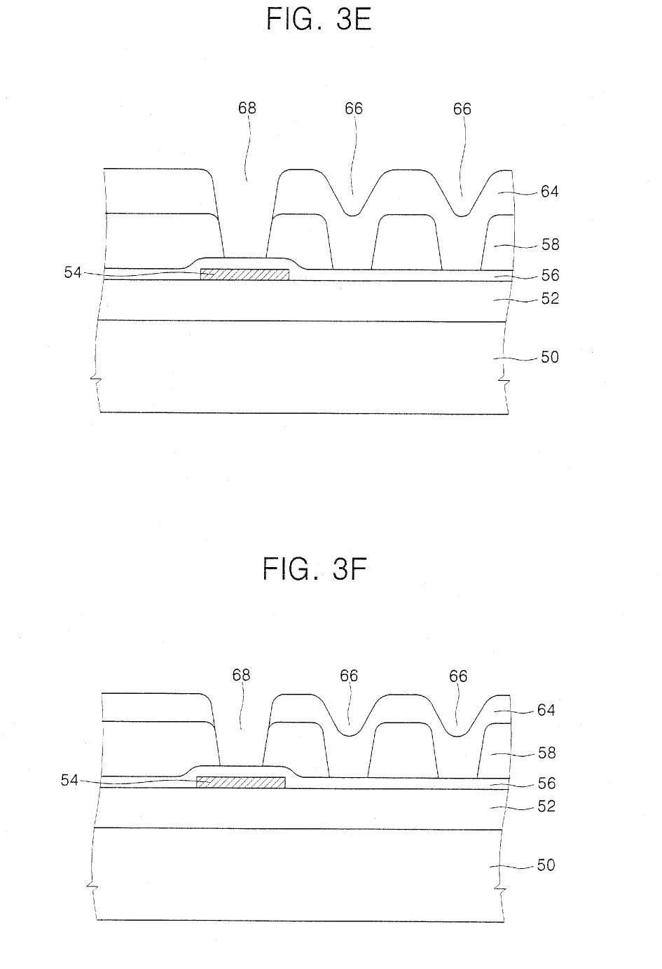

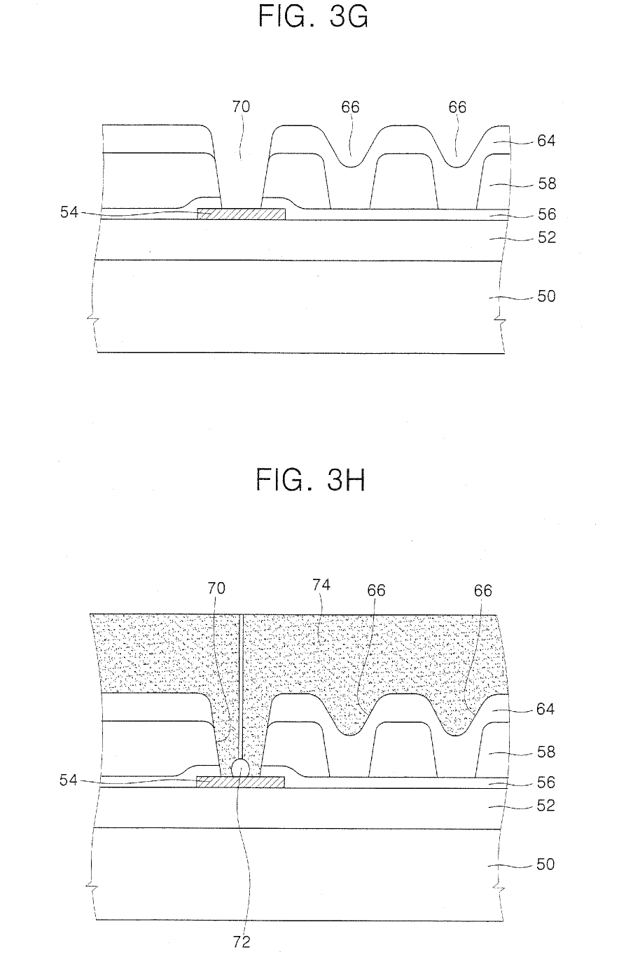

FIGS. 2A to 2F are cross-sectional views illustrating a method of fabricating a semiconductor device in accordance with some embodiments of the invention, and FIGS. 3A to 3H are cross-sectional views illustrating a method of fabricating a semiconductor device in accordance with other embodiments of the invention.

Referring to FIG. 2A, an inter-insulating layer 22 is formed on a semiconductor substrate 20. The inter-insulating layer 22 may be formed of a silicon oxide layer. A conductive layer such as a metal layer is formed on the inter-insulating layer 22. The conductive layer is patterned to form a plurality of pads 24 on the inter-insulating layer 22. A passivation layer 26 is formed on the entire surface of the semiconductor substrate having the pads 24. The passivation layer 26 may be composed of a Chemical Vapor Deposition (CVD) oxide layer and a CVD nitride layer which are sequentially stacked. A photo-sensitive polyimide layer 28 is formed on the passivation layer 26. The photo-sensitive polyimide layer 28 may be a positive type photo-sensitive material.

Referring to FIGS. 2B and 2C, the photo-sensitive polyimide layer 28 is patterned to form openings 30 which uncover the passivation layer on the pads 24. At the same time, a plurality of grooves 32 is formed on a surface of the photo-sensitive polyimide layer 28.

A mask 34 for forming a photo-sensitive polyimide layer pattern is employed in order to form the openings 30 and the grooves 32. That is, light is radiated on the mask 34 to expose the photo-sensitive polyimide layer 28. The light transmitted through the mask 34 can be radiated on the photo-sensitive polyimide layer 28. The mask 34 has a quartz substrate 36 and patterns 38 for adjusting light transmittance formed on the quartz substrate 36. The quartz substrate 36 is a transparent substrate. The quartz substrate 36 contains a first region where the pattern 38 for adjusting light transmittance is formed and a second region where the pattern 38 is not formed. Accordingly, when light is radiated on the mask 34, light transmitted through the mask 34 is composed of a first light transmitted through the pattern 38 region and a second light transmitted through the region where pattern 38 is not formed. The first light and the second light may be out of phase from each other. As a result, destructive interference of light occurs at an interface between the first light and the second light reaching the photo-sensitive polyimide layer. Accordingly, the intensity of light at the interface between the first light and the second light reaching the photo-sensitive polyimide layer becomes zero, so that the contrast of patterns formed in the photo-sensitive polyimide layer 36 through the exposure process can be enhanced.

The mask for forming the photo-sensitive polyimide layer pattern, which is employed for the method of fabricating the semiconductor device of the invention, is not limited to the above-described case. For example, the pattern 38 for adjusting the light transmittance of the mask for forming the photo-sensitive polyimide layer pattern may be used to adjust exposure energy. That is, the pattern 38 may be formed of a light absorbing material layer having a light transmittance of 6% to 8%. The pattern 38 may be formed of a molybdenum silicide layer (MoSix). The light transmittance may change depending on the thickness of the molybdenum silicide layer. Accordingly, the thickness of the molybdenum silicide layer can be selectively adjusted to have a light transmittance of 6% to 8%. The pattern 38 may be formed of molybdenum silicide oxide (MoSiO) or molybdenum silicide oxynitride (MoSiON).

The mask for forming the photo-sensitive polyimide layer pattern has an opaque pattern 40 formed on the pattern 38. The opaque pattern 40 may be formed of a material layer where light cannot be transmitted. For example, the opaque pattern 40 may be formed of one of a tungsten metal layer and a chrome metal layer.

The photo-sensitive polyimide layer 28 is exposed using the mask 34. That is, light is radiated on a surface of the photo-sensitive polyimide layer 28 using the mask 34. The light may be a wavelength described as g-line, i-line, KrF laser, or ArF laser.

In other words, the photo-sensitive polyimide layer 28 above the pads 24 is selectively exposed using the mask 34 to form a first exposure region 42. At the same time, the photo-sensitive polyimide layer 28 is selectively and partially exposed using the mask 34 to form a second exposure region 44. In this case, the first and second exposure regions 42 and 44 do not overlap each other. That is, the photo-sensitive polyimide layer except the first exposure region 42 is partially exposed to form the second exposure region 44. An exposure process for forming the first and second exposure regions 42 and 44 may be performed using the same light. Accordingly, the photo-sensitive polyimide layer can be selectively exposed using the light which has transmitted through the quartz substrate 36. At the same time, the photo-sensitive polyimide layer 28 can be selectively partially exposed using the light which has transmitted the molybdenum silicide layer patterns. The depth of the second exposure region 44 can be selectively adjusted according to the light transmittance of the molybdenum silicide layer pattern. Accordingly, the exposure process of the photo-sensitive polyimide layer can be performed using the molybdenum silicide layer pattern, so that the depth of the second exposure region 44 can be adjusted even when its width increases.

The first and second exposure regions 42 and 44 formed in the photo-sensitive polyimide layer 28 are then developed. As a result, openings 30 are formed to uncover the passivation layer 26 on the pads 24, and a plurality of grooves 32 is formed on a surface of the photo-sensitive polyimide layer 28. That is, the first exposure region 42 is developed to form the openings 30, and the second exposure region 44 is developed to form the grooves 32. Accordingly, the depth of the second exposure region can be adjusted even when its width increases, so that the passivation layer 26 cannot be uncovered via the grooves 32 even when the widths of the grooves 32 increase. Each of the grooves 32 may have a width of at least 0.3 μm.

Referring to FIG. 2D, the photo-sensitive polyimide layer having the openings 30 and the grooves 32 is subjected to a post-exposure bake process, so that it is cured. Since the grooves 32 are formed, the surface area of the photo-sensitive polyimide layer is increased. Accordingly, the contact area between the photo-sensitive polyimide layer and an epoxy molding compound to be formed on the photo-sensitive polyimide layer by a subsequent assembly process can be increased, so that adhesion between the epoxy molding compound and the polyimide layer can be enhanced.

Referring to FIG. 2E, the passivation layer 26 is etched using the cured polyimide layer having the openings 30 and the grooves 32 as an etch mask. As a result, pad windows 46 are formed to uncover the pads 24.

Referring to FIG. 2F, a ball 47 may be formed on the pad 24, and the ball 47 can be electrically connected to an external connection terminal (not shown). An epoxy molding compound 49 can then be formed, which covers the cured polyimide layer having the openings 30 and the grooves 32.

Hereinafter, methods of fabricating a semiconductor device according to other embodiments of the present invention will be described in detail.

In another embodiment, the invention is directed to methods of fabricating a semiconductor device suitable for improving reliability of the semiconductor device. The methods include forming an inter-insulating layer on a semiconductor substrate, and forming pads on the inter-insulating layer. A passivation layer and a first photo-sensitive polyimide layer are formed on the entire surface of the semiconductor substrate having the pads. The first photo-sensitive polyimide layer is patterned to form a plurality of openings uncovering the passivation layer. A second photo-sensitive polyimide layer having grooves thereon is formed on the patterned first photo-sensitive polyimide layer having the openings.

In some embodiments of the present invention, at least one of the openings may be formed to uncover the passivation layer on the pads.

In some embodiments, the methods may further include patterning the second photo-sensitive polyimide layer and the passivation layer to form a pad window uncovering the pads.

In some embodiments, the first photo-sensitive polyimide layer may have an etch selectivity with respect to the passivation layer.

In another embodiment, the invention is directed to semiconductor devices having high reliability. The semiconductor devices include a semiconductor substrate and pads on the semiconductor substrate. The semiconductor devices have a first insulating layer covering the entire surface of the semiconductor substrate having the pads. The semiconductor devices have a first photo-sensitive polyimide layer covering the first insulating layer and having a plurality of first openings uncovering the first insulating layer. The semiconductor devices have a second photo-sensitive polyimide layer covering the first photo-sensitive polyimide layer and having grooves corresponding to the first openings.

In some embodiments of the present invention, the first insulating layer may have second openings uncovering the pads.

In some embodiments, the first and second photo-sensitive polyimide layers may have third and fourth openings uncovering the pads, respectively.

In some embodiments, the semiconductor devices may further include a second insulating layer interposed between the semiconductor substrate and the pads.

In some embodiments, the semiconductor devices may include an epoxy molding compound covering the second photo-sensitive polyimide layer.

Referring to FIG. 3A, an inter-insulating layer 52 is formed on a semiconductor substrate 50. The inter-insulating layer 52 may be formed of a silicon oxide layer. A conductive layer such as a metal layer is formed on the inter-insulating layer 52. The conductive layer is patterned to form a plurality of pads 54 on the inter-insulating layer 52. A passivation layer 56 is formed on the entire surface of the semiconductor substrate having the pads 54. The passivation layer 56 may be formed of a CVD oxide layer and a CVD nitride layer which are sequentially stacked. A first photo-sensitive polyimide layer 58 is formed on the passivation layer 56. In this case, the first photo-sensitive polyimide layer 58 may have an etch selectivity with respect to the passivation layer 56. The first photo-sensitive polyimide layer 58 may be a positive type photo-sensitive material.

Referring to FIG. 3B, the first photo-sensitive polyimide layer 58 is patterned by photolithography and etching processes to form a plurality of openings which uncover the passivation layer 56. The openings consist of first openings 60 uncovering the passivation layer on the pads 54. In addition, the openings consist of second openings 62 uncovering the passivation layer outside the region where the passivation layer on the pads 54 is formed.

The second openings 62 may be formed without forming the first openings 60 while the process of patterning the first photo-sensitive polyimide layer 58 is carried out.

The process of patterning the first photo-sensitive polyimide layer 58 may be carried out using a mask for forming a photo-sensitive layer pattern. In addition, the process of patterning the first photo-sensitive polyimide layer 58 may be carried out using a typical photo mask.

Referring to FIG. 3C, a post exposure bake process is carried out on the first photo-sensitive polyimide layer having the first openings 60 or the second openings 62 to cure the first photo-sensitive polyimide layer.

Referring to FIG. 3D, a second photo-sensitive polyimide layer 64 is formed on the first photo-sensitive polyimide layer 58 having the first openings 60 or the second openings 62. As a result, a plurality of grooves 66 is formed on a surface of the second photo-sensitive polyimide layer 64. That is, the grooves 66 may be disposed to correspond to positions of the second openings 62. Accordingly, when the widths of the grooves 66 increase, the passivation layer 56 is not uncovered via the grooves 66.

The grooves 66 increase the surface area of the photo-sensitive polyimide layer. Accordingly, the contact area between the photo-sensitive polyimide layer and an epoxy molding compound to be formed on the photo-sensitive polyimide layer by a subsequent assembly process can be increased, so that adhesion between the epoxy molding compound and the polyimide layer can be enhanced.

Referring to FIG. 3E, the second photo-sensitive polyimide layer 64 is patterned by photolithography and etching processes to form third openings 68 which uncover the passivation layer on the pads 54.

If the first openings 60 were not formed during the patterning of the first photo-sensitive polyimide layer 58, the second and first photo-sensitive polyimide layers 64 and 58 are sequentially patterned by the photolithography and etching processes to form the third openings 68 which uncover the passivation layer on the pads 54.

Referring to FIG. 3F, a post exposure bake process may be carried out on the photo-sensitive polyimide layer having the grooves 66 and the third openings 68, so that the photo-sensitive polyimide layer may be cured.

Referring to FIG. 3G, the cured photo-sensitive polyimide layer having the third openings 68 may be used as an etch mask to form pad windows 70 which uncover the pads 54.

Referring to FIG. 3H, a ball 72 may be formed on the pad 54, and the ball 72 can be electrically connected to an external connection terminal (not shown). An epoxy molding compound 74 may then be formed, which covers the cured polyimide layer having the openings 70 and the grooves 66.

According to the invention as described above, a mask for forming a photo-sensitive polyimide layer pattern may be used to form a plurality of grooves on a surface of a photo-sensitive polyimide layer. In addition, the depth of the grooves can be selectively adjusted depending on the light transmittance of the mask so that the width of the grooves can be increased without uncovering the passivation layer below the photo-sensitive polyimide layer. Accordingly, the margin of the process for forming the photo-sensitive polyimide layer pattern can be improved.

In addition, another photo-sensitive polyimide layer may be formed on a photo-sensitive polyimide layer having a plurality of openings, so that the grooves having an increased width may be formed on the surface of the photo-sensitive polyimide layer. Accordingly, the grooves can be created uniformly on the surface of the photo-sensitive polyimide layer, so that the reliability of the semiconductor device can be improved.

As such, a plurality of grooves having increased depth and width can be formed on the surface of the photo-sensitive polyimide layer to increase the surface area of the photo-sensitive polyimide layer. When epoxy molding compound is formed on the grooved photo-sensitive polyimide layer, the adhesion between the two materials is improved.

The invention may be practiced in many ways. What follows are exemplary, non-limiting descriptions of some embodiments of the invention.

According to some embodiments, a method of fabricating a semiconductor device that is suitable for improving the margin of the process for fabricating the semiconductor device includes forming a photo-sensitive polyimide layer on a semiconductor substrate. The photo-sensitive polyimide layer is then patterned using a mask, and the mask has a layer for adjusting light transmittance. An epoxy molding compound is then formed on the substrate having the photo-sensitive polyimide layer patterns.

According to some embodiments, a method of fabricating a semiconductor device that is suitable for improving the margin of the process for fabricating the semiconductor device includes forming an inter-insulating layer on a semiconductor substrate and forming pads on the inter-insulating layer. A passivation layer and a photo-sensitive polyimide layer are then formed on the surface of the semiconductor substrate having the pads. The photo-sensitive polyimide layer is patterned using a mask with a layer for adjusting light transmittance to create a plurality of grooves and pad windows. An epoxy molding compound is formed on the semiconductor substrate having the patterned photo-sensitive polyimide layer.

According to some embodiments, the mask for forming the photo-sensitive polyimide layer pattern may have an opaque pattern.

According to some embodiments, the layer for adjusting light transmittance may contain a molybdenum silicide material.

According to some embodiments, the mask for forming the photo-sensitive polyimide layer pattern may have one of a tungsten metal layer pattern and a chrome metal layer pattern.

According to some embodiments, forming the grooves may include selectively and partially exposing the photo-sensitive polyimide layer.

According to some embodiments, forming the pad windows may include patterning the photo-sensitive polyimide layer on the pads to form openings uncovering the passivation layer; and etching the passivation layer using the patterned photo-sensitive polyimide layer having the openings as an etch mask.

According to some embodiments, the photo-sensitive polyimide layer may be a positive type photo-sensitive material.

Preferred embodiments of the invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the invention as set forth in the following claims.

1. A method of fabricating a semiconductor device, the method comprising:
forming a photo-sensitive polyimide layer on a semiconductor substrate;
patterning the photo-sensitive polyimide layer using a mask having a layer for adjusting light transmittance; and
forming an epoxy molding compound on the substrate having the photo-sensitive polyimide layer patterns.

2. The method of claim I, wherein patterning the photo-sensitive polyimide layer using the mask having the layer for adjusting light transmittance comprises patterning the photo-sensitive polyimide layer using a mask having an opaque pattern.

3. The method of claim 1, wherein the layer for adjusting light transmittance comprises a molybdenum silicide material.

4. The method of claim 1, wherein the mask comprises one selected from the group consisting of a tungsten metal layer pattern and a chrome metal layer pattern.

5. A method of fabricating a semiconductor device, the method comprising:
forming an inter-insulating layer on a semiconductor substrate;
forming pads on the inter-insulating layer;
forming a passivation layer on the inter-insulating layer and the pads;
forming a photo-sensitive polyimide layer on the passivation layer;
patterning the photo-sensitive polyimide layer to form a plurality of grooves and pad windows using a mask having a layer for adjusting light transmittance; and
forming an epoxy molding compound on the substrate having the patterned photo-sensitive polyimide layer.

6. The method of claim 5, wherein the mask comprises an opaque pattern.

7. The method of claim 5, wherein the layer for adjusting light transmittance comprises a molybdenum silicide material.

8. The method of claim 5, wherein the mask comprises one selected from the group consisting of a tungsten metal layer pattern and a chrome metal layer pattern.

9. The method of claim 5, wherein forming the grooves comprises selectively and partially exposing the photo-sensitive polyimide layer.

10. The method of claim 5, wherein forming the pad windows comprises:
patterning the photo-sensitive polyimide layer on the pads to form openings uncovering the passivation layer; and
etching the passivation layer using the patterned photo-sensitive polyimide layer having the openings as an etch mask.

11. The method of claim 5, wherein the photo-sensitive polyimide layer comprises a positive type photo-sensitive material.

12. A method of fabricating a semiconductor device, the method comprising:
forming an inter-insulating layer on a semiconductor substrate;
forming pads on the inter-insulating layer;
forming a passivation layer on the inter-insulating layer and the pads;
forming a photo-sensitive polyimide layer on the passivation layer;
patterning the first photo-sensitive polyimide layer to form a plurality of openings uncovering the passivation layer; and
forming a second photo-sensitive polyimide layer on the patterned first photo-sensitive polyimide layer having the openings.

13. The method of claim 12, wherein at least one of the openings uncovers the passivation layer over the pads.

14. The method of claim 12, further comprising patterning the second photo-sensitive polyimide layer and the passivation layer to form a pad window uncovering the pads.

15. The method of claim 12, wherein the first photo-sensitive polyimide layer has an etch selectivity with respect to the passivation layer.

16. A semiconductor device comprising:
a semiconductor substrate;
pads formed on the semiconductor substrate;
a first insulating layer covering an entire surface of the semiconductor substrate having the pads;
a first photo-sensitive polyimide layer covering the first insulating layer and having first openings uncovering the first insulating layer; and
a second photo-sensitive polyimide layer covering the first photo-sensitive polyimide layer and having grooves corresponding to the first openings.

17. The semiconductor device of claim 16, wherein the first insulating layer has second openings uncovering the pads.

18. The semiconductor device of claim 16, wherein the first and second photo-sensitive polyimide layers have third and fourth openings uncovering the pads.

19. The semiconductor device of claim 16, further comprising a second insulating layer interposed between the semiconductor substrate and the pads.

20. The semiconductor device of claim 16, further comprising an epoxy molding compound covering the second photo-sensitive polyimide layer.
